(19) United States
(12) Patent Application Publication
(10) Pub. No.: US 2021/0344049 A1
(43) Pub. Date: Nov. 4, 2021

(54) A SECONDARY PRISMATIC ALKALINE BATTERY TWIN CELL

(71) Applicant: CHAIRMAN, DEFENCE RESEARCH & DEVELOPMENT ORGANISATION (DRDO), New Delhi (IN)

(72) Inventors: Srinivas Kumar ADAPAKA, Andhra Pradesh (IN); Satyavani TRIUMALA VENKATA SESHA LAKSHMI, Andhra Pradesh (IN); Senthil Kumar MATHIYAZHAGAN, Andhra Pradesh (IN)

(21) Appl. No.: 17/286,288

(22) PCT Filed: Sep. 25, 2019
(86) PCT No.: PCT/IN2019/050702

§ 371 Date: Apr. 16, 2021

(30) Foreign Application Priority Data
Oct. 16, 2018 (IN) 201811039257

(51) Int. Cl. H01M 10/28; H01M 10/48; H01M 50/102; H01M 50/147; H01M 10/32; H01M 50/188; H01M 50/325

(52) U.S. Cl. CPC H01M 10/28; H01M 10/48; H01M 50/102; H01M 2300/0014; H01M 10/32; H01M 50/188; H01M 50/325; H01M 50/147

(57) ABSTRACT

A prismatic Zn—AgO secondary twin cell battery includes: an outer cell case of prismatic shape, wherein the outer cell case has bottom surface and a top surface with a cell case cover, an electrode assembly housed inside the outer cell case. The electrode assembly is formed by stacking a positive electrode plate and a negative electrode plate covered with a separator. The cell case cover is provided on the top/upper surface with a positive electrode terminal and a negative electrode terminal which seals the battery twin cell and an internal cell wall interposed in between the positive electrode plate and the negative electrode plate. The positive electrode plate and the negative electrode plate are coupled internally by crimping and potted to avoid inter cell leakage.

### FIELD OF THE INVENTION

The present invention mainly relates to a field of batteries/cells and more particularly to a prismatic Zn—AgO secondary twin cell battery which enhances safety, reduces weight, eases the assembly of battery by reducing the number of cells to be handled and increases the working space for flexible use of tools during assembly.

### BACKGROUND OF THE INVENTION

Cells are well known in the art which is a device capable of either generating electrical energy from chemical reactions or using electrical energy to cause chemical reactions. Generally, a battery consists of one or more cells, connected either in parallel, series or series-and-parallel pattern with external connections provided to power electrical devices such as flashlights, smartphones and electric cars, etc. When a battery is supplying electric power, its positive terminal is the cathode and its negative terminal is the anode.

Usually, the batteries are of two types namely primary and secondary battery. The primary batteries are used once and discarded, where the electrode materials are irreversibly changed during discharge. The secondary (rechargeable) batteries can be discharged and recharged multiple times using an applied electric current, where the original composition of the electrodes can be restored by reverse current.

Several individual Zn—AgO secondary cells each of 1.85V are required to be connected to realize the required voltage as multiples of 1.85V per cell (Ex. 1.85V×10 cells=18.5V). For connecting the cells in series, inter cell connectors (ICCs) are used. Depending on the number of cells to be connected in series or parallel, the weight of battery increases due to the requirement of deploying ICCs as inactive weight in the battery. In the case of Zn—AgO secondary battery applications, the cells are required to be monitored, during charging and all cells are required to be discharged to 1.0V after use. During assembly of battery, cells are required to be connected in series by the ICCs. During disassembly of the battery, the ICCs are required to be opened/disconnected from the battery.

In document, U.S. Pat. No. 3,353,998 relates to rechargeable alkaline battery cells operating with positive silver oxide electrodes such as, for example zinc-silver battery cells. This prior art relates to most types of porous silver electrodes used in such batteries, including positive electrode plates formed of sintered silver particles. Further, this prior art claims for an alkaline rechargeable storage battery cell having two opposite-polarity porous cell electrodes comprising a positive electrode and a negative electrode, a porous insulating separator between said two electrodes and alkaline electrolyte.

Another document, US patent US 2010/0081048 A1 discloses prismatic secondary battery and battery module using a plurality of cells. In more detail, this prior art relates to a prismatic secondary battery, a plurality of which can easily be connected without a mistake in polarity when being modularized, and to a battery module using the plurality of prismatic secondary cells. This modularization is achieved, for example, by using a method in which a positive electrode terminal and a negative electrode terminal of each battery are extended, then these extended terminals are folded toward each other, and finally the adjacent positive electrode terminal and negative electrode terminal are overlapped and welded to be connected to each other, or a method in which the adjacent positive electrode terminal and negative electrode terminal are screw-connected to each other with bolts and nuts by using a connecting member such as a bus bar.

Of these connection methods, the latter screw connection method using bolts and nuts is commonly employed. This bus bar concept is applied outside the cell top cover and further the usage of bus bars, increases the weight of battery/cell and also increases the manufacturing costs.

Therefore, there is a need in the art with a prismatic Zn—AgO secondary twin cell battery which enhances safety, reduces weight and solves the above-mentioned limitations.

### SUMMARY OF THE INVENTION

An aspect of the present invention is to address at least the above-mentioned problems and/or disadvantages and to provide at least the advantages described below.

According, in one aspect of the present invention relates to a secondary prismatic alkaline battery twin cell, the battery twin cell comprising: an outer cell case of prismatic shape, wherein the outer cell case has bottom surface and a top surface with a cell case cover, an electrode assembly housed inside the outer cell case, wherein the electrode assembly is formed by stacking a positive electrode plate and a negative electrode plate covered with a separator, the cell case cover is provided on the top/upper surface with a positive electrode terminal and a negative electrode terminal which seals the battery twin cell and an internal cell wall interposed in between the positive electrode plate and the negative electrode plate, wherein the positive electrode plate and the negative electrode plate are coupled internally by crimping and potted to avoid inter cell leakage.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings in which:

FIG. 1 shows an external perspective view of a Zn—AgO secondary prismatic twin cell formed by manipulating electrodes internally (by crimping) in series according to one embodiment of the present invention.

FIG. 2 shows an internal perspective view of Zn—AgO Secondary Prismatic Twin Cell module of FIG. 1 according to one embodiment of the present invention.

Persons skilled in the art will appreciate that elements in the figures are illustrated for simplicity and clarity and may have not been drawn to scale. For example, the dimensions of some of the elements in the figure may be exaggerated relative to other elements to help to improve understanding of various exemplary embodiments of the present disclosure. Throughout the drawings, it should be noted that like reference numbers are used to depict the same or similar elements, features, and structures.

### DETAILED DESCRIPTION OF THE INVENTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic is intended to provide.

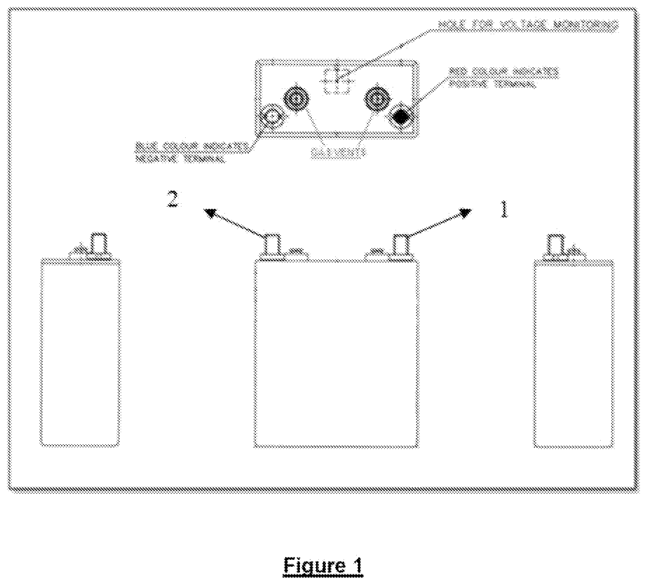

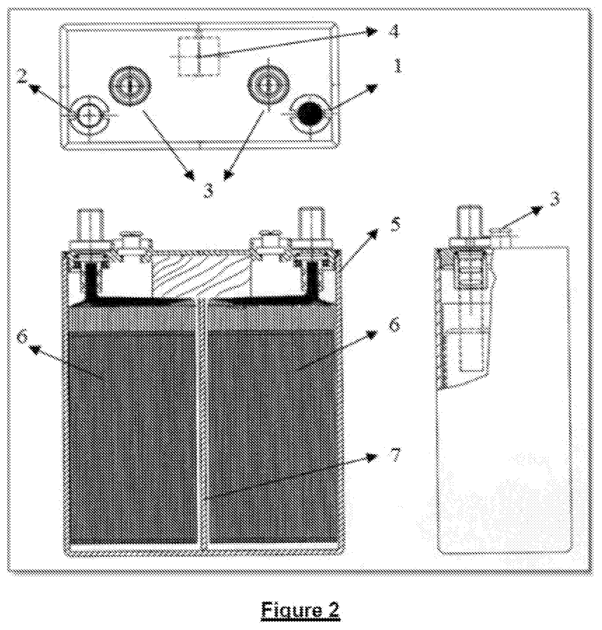

FIGS. 1 through 2, discussed below, and the various embodiments used to describe the principles of the present disclosure in this patent document are by way of illustration only and should not be construed in any way that would limit the scope of the disclosure. Those skilled in the art will understand that the principles of the present disclosure may be implemented in any suitably arranged communications system. The terms used to describe various embodiments are exemplary. It should be understood that these are provided to merely aid the understanding of the description, and that their use and definitions, in no way limit the scope of the invention. Terms first, second, and the like are used to differentiate between objects having the same terminology and are in no way intended to represent a chronological order, unless where explicitly stated otherwise. A set is defined as a non-empty set including at least one element.

The present invention provides a Zn—AgO Secondary Prismatic Twin Cell which is suitable for realizing the required voltage deploying less number (half) of inter cell connectors for assembly as compared to the existing design.

FIG. 1 shows an external perspective view of a Zn—AgO secondary prismatic twin cell formed by manipulating electrodes internally (by crimping) in series according to one embodiment of the present invention.

The figure shows an external perspective view of a Zn—AgO secondary prismatic twin cell formed by manipulating electrodes internally (by crimping) in series. In one embodiment, the secondary prismatic alkaline battery twin cell comprising: an outer cell case (5) of prismatic shape, wherein the outer cell case (5) has bottom surface and a top surface with a cell case cover, an electrode assembly housed inside the outer cell case, wherein the electrode assembly is formed by stacking a positive electrode plate and a negative electrode plate covered with a separator (6), the cell case cover is provided on the top/upper surface with a positive electrode terminal (1) and a negative electrode terminal (2) which seals the battery twin cell and an internal cell wall (7) interposed in between the positive electrode plate and the negative electrode plate, wherein the positive electrode plate and the negative electrode plate are coupled internally by crimping and potted to avoid inter cell leakage.

The battery twin cell is a Zn—AgO twin cell, where the Zn and AgO electrodes (i.e. positive electrode plate and the negative electrode plate) are suitably manipulated and integrating them internally delivers about 3.7V. The two cell stacks (i.e. positive electrode plate and the negative electrode plate) are assembled in a single case (container) with partition (internal cell wall (7)) between the stacks. By suitably manipulating Zn and AgO electrodes (anode and cathode) and integrating them internally, a single cell delivering 3.7V (OCV) is fabricated as Zn—AgO twin cell. The anode terminals and cathode terminals in the cell are electrically connected inside. Owing to this internal electrical integration in the present invention, the twin cell enhances safety, reduced weight and eases assembly of battery by reducing the number of cells (by half) to be handled while increasing the working space for operation of tools during assembly.

FIG. 2 shows an internal perspective view of Zn—AgO Secondary Prismatic Twin Cell module of FIG. 1 according to one embodiment of the present invention.

The figure shows an internal perspective view of Zn—AgO Secondary Prismatic Twin Cell module of FIG. 1. The Zn—AgO secondary prismatic twin cell includes a cell outer cell case (5) of prismatic shape that has a bottom and a cell case cover at the top, an electrode assembly that is housed in the cell case and formed by stacking a positive electrode plate and a negative electrode plate with a separator (6) interposed in between, and a cell case cover which is provided on the upper surface with a positive electrode terminal (1) and a negative electrode terminal (2). This case cover also seals the cell.

Two cell stacks are assembled in a single case (container) with partition between the stacks. Each integrated cell will have two terminals outside, with red marking on one terminal for positive and with blue marking for negative. The two cell stacks are connected internally with a crimp design and potted to avoid inter cell leakage. A provision (hole (4)) is provided on top of cover for monitoring the voltage during charging/discharging. Each stack is fitted with separate rubber sheathed valve assembly (gas vents (3)) to vent out the gases which are generated during storage/discharge/charge.

Integrating two numbers of 1.85 V cells internally in series results in a 3.7 V (OCV) Zn—AgO cell. A negative electrode terminal (2) and a positive electrode terminal (1) of Zn—AgO secondary cells in the present invention are electrically connected. The Zn—AgO secondary prismatic alkaline battery twin cell which enhances the safety while reducing weight. The concept of internal crimping of positive electrode plate and the negative electrode plate is not restricted only to Zn—AgO cell may also be implemented in other types of batteries/cells. It also eases the assembly of battery by reducing the requirement of number of cells to realize a specific voltage to be handled and also increases the working space for operation of tools during assembly. The concept of connecting two cells internally is being attempted for the first time in the field of Zn—AgO secondary battery technology.

Those skilled in this technology can make various alterations and modifications without departing from the scope and spirit of the invention. Therefore, the scope of the invention shall be defined and protected by the following claims and their equivalents.

FIGS. 1-2 are merely representational and are not drawn to scale. Certain portions thereof may be exaggerated, while others may be minimized. FIGS. 1-2 illustrate various embodiments of the invention that can be understood and appropriately carried out by those of ordinary skill in the art.

In the foregoing detailed description of embodiments of the invention, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus, the following claims are hereby incorporated into the detailed description of embodiments of the invention, with each claim standing on its own as a separate embodiment.

It is understood that the above description is intended to be illustrative, and not restrictive. It is intended to cover all alternatives, modifications and equivalents as may be included within the spirit and scope of the invention as defined in the appended claims. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein,” respectively.

1. A secondary prismatic alkaline battery twin cell, the battery twin cell comprising:
an outer cell case of prismatic shape, wherein the outer cell case has bottom surface and a top surf ace with a cell case cover;
an electrode assembly housed inside the outer cell case, wherein the electrode assembly is formed by stacking a positive electrode plate and a negative electrode plate covered with a separator, the cell case cover is provided on the top/upper surface with a positive electrode terminal and a negative electrode terminal which seals the battery twin cell; and
an internal cell wall interposed in between the positive electrode plate and the negative electrode plate, wherein the positive electrode plate and the negative electrode plate are coupled internally by crimping and potted to avoid inter cell leakage.

2. The battery twin cell as claimed in claim 1, wherein the two cell stacks (i.e. positive electrode plate and the negative electrode plate) are assembled in a single case (container) with partition (internal cell wall) between the stacks.

3. The battery twin cell as claimed in claim 1, wherein the battery twin cell is a Zn—AgO twin cell, where the Zn and AgO electrodes (i.e. positive electrode plate and the negative electrode plate) are suitably manipulated and integrating them internally delivers about 3.7V.

4. The battery twin cell as claimed in claim 1, wherein each integrated cell has two terminals externally to indicate the polarity, i.e. with red marking for positive and with blue marking for negative.

5. The battery twin cell as claimed in claim 1, further comprising a provision which is provided on top/upper surface of cell case cover for monitoring the voltage during charging/discharging.

6. The battery twin cell as claimed in claim 1, wherein each stack is fitted with a separate rubber sheathed valve assembly to vent out the gases which are generated during storage/discharge/charge.

7. The battery twin cell as claimed in claim 1, wherein the battery twin cell is a Zn—AgO secondary prismatic alkaline battery twin cell which enhances safety, reduces weight, eases the assembly of battery by reducing the number of cells to be handled and also increases the working space for operation of tools while assembly.
